(19) United States
(12) Patent Application Publication
(10) Pub. No.: US 2023/0207379 A1
(43) Pub. Date: Jun. 29, 2023

(54) METHOD AND DEVICE FOR BONDING SUBSTRATES

(71) Applicant: EV Group E. Thallner GmbH, St. Florian am Inn (AT)

(72) Inventors: Dominik ZINNER, St. Florian am Inn (AT); Thomas WAGENLEITNER, St. Florian am Inn (AT); Jürgen Markus SÜSS, St. Florian am Inn (AT); Thomas PLACH, St. Florian am Inn (AT); Jürgen MALLINGER, St. Florian am Inn (AT)

(73) Assignee: EV Group E. Thallner GmbH, St. Florian am Inn (AT)

(21) Appl. No.: 17/928,134

(22) PCT Filed: Jun. 29, 2020
(86) PCT No.: PCT/EP2020/068231

§ 371 Date: Nov. 28, 2022

(51) Int. Cl. H01L 21/687; H01L 23/00

(52) U.S. Cl. CPC H01L 21/68785; H01L 24/83; H01L 2224/83894

(57) ABSTRACT

A substrate holder for curving a substrate
the substrate holding including a fixing plate for fixing the substrate,
curving means for curving the fixing plate,
wherein the fixing plate is constituted such that the curvature of the substrate can be adjusted in a targeted manner, as well as a corresponding method.

### FIELD OF INVENTION

The invention describes a substrate holder, a device and a method for bonding two substrates according to the coordinated claims.

### BACKGROUND OF INVENTION

The prior art shows a large number of different substrate holders. In particular in fusion bonding, the substrate holders are always more complicated and more elaborate in order to meet the ever-increasing demands of the bonding process. In the publication WO 2012083978A1, a substrate holder was mentioned which can compensate for local and/or global distortions through active control by means of thermo-, piezo- or fluid elements. The substrate holder of publication WO 2013023708A1 shows possible ways of avoiding contamination of the rear side of a substrate as far as possible, as well as a method for the release of the substrate by a targeted control of the fixing elements. Publication WO 2017162272A1 shows a substrate holder which comprises a plurality of fixings zones, which are distributed in particular symmetrically over the substrate holder and can be switched individually. Publication WO 2018028801A1 shows a method for fixing a substrate not radially symmetrically, but uniaxially and also of releasing the latter in its uniaxial curvature. In publication WO 2014191033A1, a substrate holder is disclosed, the surface whereof is curved or can be curved in order to provide a substrate fixed thereon with an inhomogeneous curvature, before and/or while it is bonded. Publication WO 2014191033A1 mentions, in particular on page 9, that the adjustable curvature is not homogeneous, i.e. an inhomogeneous curvature. With each new generation of substrate holders, better and quicker bonding results have been achieved, which however can still be optimised by further technological improvement. In the meantime, it has been recognised that the two substrate holders are of decisive importance in the bonding process. In particular, the control of an advancing bonding wave in a fusion bond is extremely important for a correct bonding result. The control is in particular also influenced by the way in which the substrates participating in the bonding process are curved.

One of the problems in the prior art is the fact that not only the surface on which the substrate is fixed is curved in a well defined manner, but also that other components of the substrate holder are mechanically influenced, in particular curved, during the curving process. In terms of design, a substrate holder would be possible in a solid construction, i.e. a construction comprised of very thick and solid parts which have a great bending resistance. However, some substrate holders have to be designed small and compact, i.e. relatively delicate, and therefore necessarily have a relatively low bending resistance. This low bending resistance then causes a slight, undesired, elastic deformation of some parts of the substrate holder, which should not actually be curved. These elastic deformations and curvatures retroact on the surface on which the substrate is fixed, the fixing plate surface, and thus influence the curvature of the substrate. It must be mentioned that the arising elastic deformations naturally occur only around the nanometre or micrometre range, but elastic deformations of this order of magnitude are already sufficient to obtain a negative retroaction on the fixed substrate and its curvature.

It is possible to produce a homogeneous, curved fixing surface on a substrate holder by milling, grinding, polishing, etching and lapping processes, so that the substrate fixed thereon also has a homogeneous curvature. This fixing surface is however static and could not change the curvature. On the other hand, it would be possible to construct a substrate holder, which can indeed curve the fixing surface, as in publication WO 2014191033A1. With these substrate holders, however, it emerges that it is very difficult to adjust the curvature of the fixing surface and therefore the curvature of the substrate in a targeted manner as a function of location, in particular to keep it constant. Above all, the adjustment of a homogeneous curvature of the substrate is very difficult, cannot be implemented at all or at least cannot be so reproducibly.

### SUMMARY OF INVENTION

A problem to be solved by the present invention includes removing the drawbacks of the prior art and in particular in providing an improved substrate holder, an improved device and an improved method for bonding.

This problem is solved with the features of the coordinated claims. Advantageous developments of the invention are given in the sub-claims. All combinations of at least two features given in the description, in the claims and/or the drawings also fall within the scope of the invention. In stated value ranges, values lying inside the stated limits are also deemed to be disclosed as limiting values and can be claimed in any combination.

It is in particular of technical importance to design a substrate holder in such a way that it curves a substrate adjustably in a targeted manner, in particular homogeneously.

The invention relates to a substrate holder for curving a substrate, comprising
a fixing plate for fixing the substrate,
curving means for curving the fixing plate,
   wherein the fixing plate is constituted such that the curvature of the substrate or of the fixing plate can be adjusted in a targeted manner.

The fixing plate has a front side, on which the substrate is fixed, and a rear side facing away from the front side. The fixing plate has a width, a length and a thickness. In another embodiment, the fixing plate is designed radially symmetrical and is then defined by a radius and a thickness. The width and the length extend in the direction of a fixing plate surface on the front side of the fixing plate, on which the substrate is fixed. The thickness extends perpendicular to the fixing plate surface.

The thickness of the fixing plate preferably varies, i.e. the thickness is not the same at every point, but rather the fixing plate is thicker at at least one point of the fixing plate than at another point. Special embodiments/preferred forms are described in the following text.

Provision is preferably made such that a homogeneous curvature of the fixing plate or of the substrate can be adjusted.

Provision is preferably made such that the fixing plate is mounted in a hinged manner.

Adjustable in a targeted manner means that the value of the curvature can be predefined. Homogeneous means that, with a predefined value of the curvature, this curvature is the same, i.e. constant, at every position of the fixing plate of the substrate, within a vanishingly small error tolerance.

The rear side of the fixing plate is preferably formed such that a homogeneous curvature of the fixing plate results or that a homogeneous, i.e. the same that every point, curvature of the fixing plate or the fixing plate front side and therefore of the substrate can be adjusted.

In a preferred embodiment, but also as an independent inventive aspect, the substrate holder is designed such that reaction forces and/or moments produced during the curving of the fixing plate can be compensated by at least one compensation means.

As an independent inventive aspect, the invention relates to a substrate holder for curving a substrate, comprising

a fixing plate for fixing the substrate,

curving means for curving the fixing plate,

wherein reaction forces produced during the curving of the fixing plate can be compensated by at least one compensation means.

The invention also relates to a device, in particular a bonding device, comprising at least one substrate holder according to the invention.

The invention also relates to a method for bonding two substrates, comprising the following steps, wherein:
a first substrate is fixed on a first substrate holder in particular according to the invention,
a second substrate is fixed on a second substrate holder in particular according to the invention,
the substrates (7) are aligned with respect to one another,
at least one of the substrates (7) is curved,
the substrates are brought into contact,
   wherein the curvature of at least one of the substrates or of the fixing plate is adjusted in a targeted manner, is preferably homogeneous.

Preferably and as an independent inventive aspect, during the curving of the fixing plate, the moments and/or reaction forces produced in the remaining components are either compensated for, but preferably are not even transferred at all to the fixing plate or only to a small extent.

A further independent aspect of the invention thus relates to a method for bonding two substrates, comprising the following steps, wherein:
a first substrate is fixed on a first substrate holder in particular according to the invention,
a second substrate is fixed on a second substrate holder in particular according to the invention,
the substrates are aligned with respect to one another,
at least one of the substrates is curved,
the substrates are brought into contact,

wherein, during the curving of the fixing plate, the moments and/or reaction forces produced in the remaining components are either compensated for, but preferably are not even transferred at all to the fixing plate or only to a small extent. This is preferably brought about by the use of a bearing, by means of which reaction forces and/or moments that are as small as possible or only very small are transferred.

Provision is preferably made such that the fixing plate is thicker in the centre than at the edge. A particularly homogeneous curvature of the fixing plate and of the substrate can thus advantageously be achieved. The fixing plate is preferably formed tapered towards the edge. Provision is preferably made such that the fixing plate is formed symmetrically with respect to the centre.

The essential inventive aspect of the present invention is that a curvature can be imparted to a substrate which can be adjusted in a targeted manner. In particular it is possible to produce curvatures with a constant, i.e. homogeneous, radius of curvature. The adjustment of a constant curvature represents the most preferred inventive approach towards producing a bond. By means of an inventive extension of the embodiments, the reaction forces, which necessarily always arise according to Newtonian's third law, are not absorbed by the components of the substrate holder, which are connected via mechanical coupling to the plate which fixes the substrate, but by a second plate, the compensation plate, which is located in the interior of the substrate holder and is freely mounted (hinged) together with the first plate, i.e. in the ideal case can transfer no moment or only a vanishingly small one.

A curvature is understood to mean the deviation of the shape of an object from an unloaded initial state, in particular characterised in that the position of the centre line or the centre area of the object changes under load.

The curvature is described in the simplest way as a reciprocal value of the radius of curvature for a point of the curve. The radius of curvature at a point is the radius of the osculating circle on the curve through this point. The greater the curvature radius, the smaller the curvature.

In the semiconductor industry, the expression “bow” still exists. This is understood to mean the deviation of the centre point of the median area of the substrate of a free unclamped substrate, in particular a wafer, from the median area of the reference plane. The reference plane is simply a horizontal, flat plane, on which the substrate lies clamped. The precise definition can be found in the now out-dated ASTM F534 standard.

In the subsequent text, bending line and bending area are used as synonyms, in particular since the substrate holders according to the invention are preferably shown in cross-section in the figures and therefore only a bending line can be seen instead of a bending area. The expert in the field understands that a two-dimensional surface of a three-dimensional body generally has a bending area and that only a bending line can be seen or represented in cross-section through such a bending area.

In the particularly preferred embodiments of the substrate holders and method according to the invention, a substrate is curved with a constant curvature, i.e. the curvature is the same as every position of the substrate. The curvature is then also referred to as homogeneous. A constant curvature of a substrate produces particularly optimum bonds between two substrates. Such a curvature can be achieved in particular when it is ensured that no reaction forces and/or moments of other components retroact on the fixing plate. This is preferably brought about by the use of a bearing, which permits no transfer or only a very small transfer of reaction forces and/or moments.

In general, the curvature can also vary over the substrate. However, the curvature is preferably radially symmetrical, i.e. it changes only with the radial position measured from the centre of the substrate, but not with the angle. Substrates which form anisotropic curvatures, i.e. the curvature of which generally varies with the radius position and the angle, have the property of forming saddle surfaces. Since the rigidity of the fixing plate according to the invention, in particular of the entire substrate holder according to the invention, is however much greater than the rigidity of the substrate and the substrate is fixed by a fixing element on the fixing plate, it can be assumed that the substrate makes contact with the fixing plate at every point. In this case, the constraint, which does not permit the emergence of a curvature in the form of a saddle surface, would lead to inherent stresses in the substrate.

The curvature radius of a plate or of a substrate is greater than 0.01 m, preferably greater than 0.1 m, still more preferably greater than 1 m, most preferably greater than 10 m, with utmost preference greater than 100 m.

If the curvature radius along the bending line or the bending area is not constant, the absolute amount of the difference between the largest and smallest curvature radius is less than 1 m, preferably less than 0.1 m, still more preferably less than 0.01 m, most preferably less than 0.001 m, with utmost preference less than 0.0001 m.

The bow is less than 1000 μm, preferably less than 500 μm, still more preferably less than 100 μm, most preferably less than 10 μm, with utmost preference less than 1 μm.

The embodiments and method according to the invention can preferably curve a substrate in such a way that the surface in cross-sectional profile or the bending line can be described by one of the following mathematical functions:

elliptical section, preferably
circular section

parabola

hyperbola

sine, in particular in the value range [0, Pi]

Negative hyperbolic cosine

The bending area can then be described in particular by one of the following functions.

ellipsoidal section, in particular
circular shell section

paraboloid

hyperboloid

Generally, the bending areas are therefore the surfaces arising by rotation of the bending lines.

Of all the aforementioned possible bending line or bending area shapes, the ones which have a homogeneous curvature, i.e. the circular sections or circular shell sections, are the most preferred.

This preferred adjustability of a homogeneous curvature is produced by a precisely defined and precisely produced hollow plate surface of the fixing plate. Through the production of a hollow plate surface of the fixing plate in a defined and precise manner, the final shape of the fixing surface of the fixing plate and therefore of the substrate is precisely defined. In particular, use is made of calculation methods, preferably finite elements methods, in order to determine the shape of the hollow plate surface of the fixing plate. The shape of the hollow plate surface of the fixing plate can be described in particular by one of the aforementioned mathematical functions.

The actual shape of the hollow plate surface of the fixing plate to be produced depends, however, on many factors . . .
bending resistance of the fixing plate
bending resistance of the entire substrate holder
curving means used, in particular
   employed fluid pressure when use is made of a fluid
etc.

The inventive idea includes precisely producing only a single rigid hollow plate surface of the fixing plate and then, with the latter, being able to adjust any curvature on the fixing surface of the fixing plate and therefore on the substrate by means of the controllable adjustment means, in particular such that the curvature on the substrate is homogeneous, i.e. the same at every point.

According to the invention, this method of curving a substrate adjustably in a targeted manner by the creation of a precisely produced hollow plate surface of the fixing plate is further assisted and improved by the fact that at least one compensation means is used in order to reduce or completely prevent a mechanical retroaction during the curving of the fixing plate.

Provision is preferably made such that the at least one compensation means comprises an, in particular curvable, compensation plate.

Provision is preferably made such that the compensation plate can be curved against the curvature of the fixing plate.

Provision is preferably made such that a, preferably sealed, intermediate space can be created between the fixing plate and the compensation plate.

Provision is preferably made such that the curvature of the fixing plate and of the compensation plate can be produced by means of a fluid, which can be pressed into the intermediate space.

Provision is preferably made such that the intermediate space can be produced by a fluid means, a mechanical adjustment means and/or electrostatic forces.

Provision is preferably made such that the fixing plate and the compensation plate are connected to one another via a, preferably hinged, bearing.

Provision is preferably made such that the fixing plate and the compensation plate are connected via a, preferably hingeded, bearing to the remaining components of the substrate holder.

Provision is preferably made such that only a small moment, preferably no moment, can be transferred via a periphery of the fixing plate and/or the compensation plate. The transferred moment is less than 1 Nm, preferably less than 10⁻³ Nm, still more preferably less than 10⁻⁵ Nm, most preferably less than 10⁻⁷ Nm, with utmost preference 0 Nm.

Provision is preferably made such that the compensation plate comprises a closed groove, preferably around the entire circumference, in its outer region. The distance between the groove and the outer periphery of the compensation plate is less than 50 mm, preferably less than 40 mm, still more preferably less than 30 mm, most preferably less than 20 mm, with utmost preference less than 10 mm.

Provision is preferably made such that the compensation plate comprises a sealing means, preferably a sealing ring, in its outer region, wherein the sealing means is preferably arranged on a closed platform, in particular around the entire circumference. The sealing ring permits the generation of a pressure of more than 1 bar, preferably more than 1.2 bar, still more preferably more than 1.5 bar, most preferably more than 2 bar, with utmost preference more than 2.5 bar.

Provision is preferably made such that the at least one compensation means comprises a hinged bearing of the fixing plate. The hinged bearing, which is not able to transfer reaction forces and/or moments from other components of the substrate holder according to the invention to the fixing plate, is thus itself regarded as a compensation means in the sense of this disclosure.

A further preferred embodiment of the invention is based in particular on the idea of designing a substrate holder, which comprises two plates which can be curved in two respectively opposite directions. The curving takes place by adjustment means (also referred to in the following as curving means), in particular by the use of a fluid, which is pressed into the intermediate space of the two plates. Through the use of two plates, the reaction force produced by the deformation of the first plate does not act on the underside of the substrate holder which holds the first plate, but rather on the second inserted plate according to the invention. A harmful and influencing retroaction of the reaction force on the substrate holder and therefore the substrate is thus eliminated. The reaction force is instead absorbed (compensated for) by the second plate, which can freely deform in the direction of the substrate holder. Furthermore, the invention describes a device, in particular a bonding device, which uses the substrate holder according to the invention at at least one side of the device.

### Substrate Holder

The substrate holder according to the invention is described in detail in the following. In particular, it is important to understand all the design-related measures, with the aid of which an adjustable, in particular homogeneous curvature of can be produced. Furthermore, design-related measures are disclosed, with the aid of which the forces and moments retroacting on the upper plate, as well as their avoidance can be understood.

All substrate holders according to the invention comprise a fixing surface. The fixing surface is in particular part of a fixing plate. The fixing plate has a hollow surface lying opposite the fixing surface. The hollow surface is preferably formed according to a mathematical function.

The shape of the hollow surface produces, by means of an adjustment element, a well-defined, in particular homogeneous curvature.

The normal component of a force which acts on a lever produces a moment in the point of application of the lever. In order to simplify the representation of the invention, reference will always be made only to forces in the remainder of the text, although the forces arising also cause moments. The sum of the moments and the sum of the forces must be zero. All consequences arising therefrom are thus also deemed to be disclosed.

The substrate holders according to the invention are preferably always designed such that a force curves an upper, first plate and the counterforce thereby arising is not absorbed by other components which mount or hold the plate, but by compensation components specially provided for this, in particular a second, lower plate. The second, lower plate must also not be mechanically connected or only very weakly so to the remaining components of the substrate holder, since they would otherwise again be mechanically coupled with the upper first plate and could transfer a moment. A characteristic feature must include the fact that no moment or at least only a vanishingly small moment can be transferred via the periphery, in particular of both plates. The plate, as well as some other necessary machine elements, therefore must preferably form an ideal floating bearing, in particular a bearing that is as ideal as possible, at the periphery.

In a special preferred embodiment, the substrate holder according to the invention therefore comprises at least two plates, which can be curved and in particular are mounted in a hinged manner.

In a first special, preferred embodiment according to the invention, the plates themselves are the adjusting element which bring about their curvature, in that the plates are set at a potential, a surface charge is generated and electrostatic forces provide for the curving of the plates. The plates are electrically insulated from one another. In such an insulation, the surfaces at the periphery of the substrates are made from a dielectric material or have been coated with a dielectric material.

Other partial areas of the plates, in particular the surfaces of the plates, which are trued up with one another, are electrically conductive. In particular, the entire plates are electrically conductive with the exception of their insulating edge regions. Both plates can be set at an, in particular positive, potential with respect to earth. It is also conceivable that both plates are set at a negative potential with respect to earth. As a result of the unipolar charging of the two plates, the two plates repel one another. If the plates were not electrically insulated at their periphery, the charges would move to the outer surfaces of the two plates. No charges would be present at the inner surfaces of the two plates facing the hollow, and the hollow would be field-free.

Accordingly, the plates would not be able to curve outwards according to the invention. The electrical insulation of the two plates put at potential is therefore an essential inventive aspect of this very special embodiment. In a special extension of the embodiment according to the invention, areas of the two plates electrically insulated from one another can be electrically conductive and each of these electrically conductive areas can be put at a well-defined electrical potential individually and independently of the other electrical areas.

It is thus possible to precisely adjust the repulsion of the plates locally. The finer the segmentation of the electrically conductive areas, the more precise the local resolution of the adjustable curvature.

In a second special, preferred embodiment according to the invention, the two plates are curved by a mechanical adjustment element, which is located between the plates. The mechanical adjustment element can be operated electrically and/or pneumatically and/or hydraulically. Particularly preferably, piezoelectric piles are used as adjustment means. In particular, the use of a plurality of such mechanical adjustment elements is also again possible, which are located on a plurality of, in particular symmetrical, positions between the plates. In this case, each of the adjustment means can preferably again be adjusted independently of all the other adjustment means.

In a third, special particularly preferred embodiment according to the invention, the plates are curved by a fluid, which is introduced, in particular pumped, into an intermediate space. The fluid is a liquid, a liquid mixture, a gas or a gas mixture. Most preferably, the fluid is air. An in particular symmetrical curvature of the two plates thus occurs.

The inventive idea behind the special embodiments according to the invention includes the fact that the lower plate can freely expand and does not transfer any force and/or any moment to the remaining components of the substrate holder, so that the latter is not deformed. In particular, the curvature of the first plate, the fixing plate, and therefore the curvature of the substrate fixed thereon, should not be changed by a mechanically retroacting moment or a mechanically retroacting force.

### Plates

The substrate holder according to the invention comprises in particular at least one plate specially shaped at its rear side. In a special embodiment according to the invention, the substrate holder comprises two plates.

There are two basic types of plates, the fixing plate and the compensation plate. The fixing plate is the plate on which the substrate to be curved is fixed. The compensation plate is the plate which assumes the inventive effect of absorbing the forces and/or moments of the adjustment means and thus largely prevents a mechanical retrocoupling to the other components of the substrate. In particular, the mounting of the plates is also decisively responsible for the fact that no forces and/or moments are transferred from other components to the fixing plate.

The space between the two plates is referred to as a hollow. All the plates comprise a hollow plate surface and a second plate surface lying opposite the hollow plate surface, said second plate surface being used differently depending on the function of the plate.

The hollow plate surface is always the surface which is facing the hollow between the two plates. In a particularly preferred embodiment according to the invention, the hollow plate surfaces are specially shaped. In particular, the hollow plate surface of the plate which fixes the substrate has a well-defined shape, which acts in a positive manner on the curving behaviour of the plate and therefore on the curving behaviour of the substrate.

If a distinction between the hollow plate surface of the fixing plate and of the compensation plate is required, then the latter are referred to correspondingly as hollow fixing plate surface and hollow compensation plate surface. The hollow plate surfaces are shaped arbitrarily, but can preferably be described according to a function, which has already been used for the description of the bending line or bending area. All the functions disclosed for the bending line and/or the bending area are therefore also deemed to be disclosed for the description of the hollow plate surfaces.

The plate surface which fixes a substrate is referred to as a fixing plate surface. A fixing plate surface can accordingly always be found only on a fixing plate.

The fixing plate surface comprises fixings in order to fix the substrate. The fixings can in particular be

1. mechanical fixings, in particular

1.1. clamps

2. vacuum fixings, in particular with
2.1. individually controllable vacuum tracks
2.2. vacuum tracks connected to one another
   3. electrical fixings, in particular
3.1. electrostatic fixings
   4. magnetic fixings
   5. adhesive fixings, in particular
   6. Gel-Pak fixings and/or
   7. fixings with adhesive, in particular controllable surfaces.

The fixings are in particular pneumatically and/or hydraulically and/or electronically controllable.

The vacuum fixing is the preferred type of fixing. The vacuum fixing preferably comprises a plurality of vacuum tracks, which emerge at the surface of the substrate holder. The vacuum tracks are preferably individually controllable. In a technically more feasible application, several vacuum tracks are united to form vacuum zones, which are individually controllable, and can therefore be evacuated and flooded individually. Each vacuum zone is however independent of the other vacuum zones. The possibility of constituting individually controllable vacuum zones is thus obtained. The vacuum zones are preferably designed annular. A targeted, radially symmetrical fixing and/or release of a substrate from the sample holder, which in particular is performed from the inside outwards, is thus enabled.

In a further improvement, the vacuum zones segmented in an annular form are again segmented along an annular circumference, so that each vacuum zone is split up along the annular circumference into a plurality of vacuum zones. Such embodiments have been disclosed in detail in publication WO 2017162272A1.

In a very particularly preferred embodiment according to the invention, so-called pins are located on the fixing plate surface. Publication WO2015113641A1 mentioned such a structure. By means of these pins, a substrate does not lie over the whole area, but rather contacts the fixing surface for the most part only on the pins. On the one hand, contamination is thus reduced, on the other hand a vacuum can be created in the intermediate spaces of the pins along the entire fixing surface of the fixing plate. In particular, the pins are grouped in the vacuum zones which have already been mentioned. These embodiments have also been disclosed in detail in publication WO2017162272A1. In particular, the grouping of the pins and vacuum feed-throughs to the vacuum zones, which are distributed on the fixing plate and in particular can be controlled individually, is hereby explicitly disclosed and, in connection with the actual inventive idea, represents a decisive improvement in the substrate holder according to the invention.

Although the mentioned use of vacuum zones according to publication WO2017162272A1, which can in particular each be evacuated or flooded through at least one vacuum hole, is deemed to be a special beneficial and important extension of the inventive idea, the substrate holders according to the invention will be described in the subsequent text with a fixing method, in which not only a very small number of vacuum holes, in particular in the centre, are located on the fixing plate surface.

In the embodiments according to the invention, in which a fixing of the substrate takes place by means of a vacuum fixing, the vacuum between the substrate and the fixing plate surface is preferably produced via vacuum holes, which are drilled along a circle, the circle centre point of which is the centre of the fixing plate. With the use of the substrate holder with pins (pins chuck), it is thus possible to position one of the pins precisely in the centre of the fixing plate, which has a demonstrably positive effect on the bonding result. A precise description and representation is made in the description of the figures and the figures. It is therefore a further feature according to the invention to disclose a substrate holder with pins, which has one of the pins precisely beneath the position at which the first contact of the two substrates occurs. By means of such a pin beneath the contact point of the two substrates, there is a mechanical stabilisation of the substrates at this point. Since the bonding wave begins to run outwards from this point, the coincidence of such a pin with the contact point along a line normal to the fixing plate surface is decisive for a stable start of the bonding wave. Illustratively, the effect of a pin precisely beneath the contact point can be represented such that the pin beneath the contact point prevents pushing-through of the substrates at this point and therefore creates a stable mechanical starting situation.

The second plate is a compensation plate. The compensation plate preferably has a closed groove around the entire circumference in an outer region. The groove serves to ensure that the curving of the lower plate does not continue completely up to its edge, but mainly up to this groove. The groove thus intercepts curving before it reaches the periphery. A small retroaction on the substrate holder that is still possible is thus further reduced. If the mounting of the compensation plate at the periphery is so good so that no moment is transferred, such a groove could be dispensed with. Nonetheless, the embodiment of such a groove is actually always beneficial. The compensation plate preferably also carries sealing means, in particular a sealing ring. The sealing means is preferably located on a small closed platform extending around the entire circumference.

### Device

All the substrate holders according to the invention can be used in a device according to the invention for the fixing of a lower and/or upper substrate. Particularly preferably, the substrate holders according to the invention are used in a bonding device for the fixing of the lower and the upper substrate. The control of the bonding, in particular fusion bonding, is thus particularly improved and optimised. Through the use of the substrate holder according to the invention as an upper side substrate holder, the curving pin long used in the semiconductor industry, which has initiated the central curving of a substrate, is in particular replaced.

The preferred embodiment of a device according to the invention also comprises using a substrate holder according to the invention for the fixing of the upper substrate and a substrate holder according to the invention for the fixing of the lower substrate.

A special device according to the invention comprises a substrate holder according to the invention at the underside and any other substrate holder not according to the invention. The upper substrate holder preferably comprises the curving means known in the prior art, in particular a curving pin or a nozzle, from which a fluid exits which correspondingly curves the upper substrate.

In a particular extension of a device according to the invention, an alignment device (aligner) is also present in the bonder.

If the substrates are transparent for electromagnetic radiation of a certain frequency, observation devices are preferably present in order to analyse the course of the bonding wave. In this way, not only can the bonding process be observed, influenced and if need be interrupted, but also the behaviour of the bonding wave as a function of different parameters can be analysed. Such an analysis assists with the further improvement of the substrate holders according to the invention.

In a particular extension of the device according to the invention, the following modules can be connected to the device according to the invention, in particular in a vacuum-tight manner.

Cleaning modules

Grinding modules

Etching modules, in particular
for chemical etching
for physical etching

Plasma modules

Coating modules

Such modules are preferably part of a so-called cluster device, in which there are vacuum-tight gates between the modules. Locks are preferably also present between some of the aforementioned modules. The modules can be arranged in an arbitrary manner with respect to one another. Preferably, there is a central module, in which a robot is located, which can transport the substrates between the individual modules. Such a centrally arranged cluster is referred to as a star cluster. It is also conceivable that the modules are arranged in a row.

### Method

The method according to the invention includes the following steps. The steps do not necessarily have to proceed in the stated sequence.

In a first process step according to the invention, loading and fixing of a first substrate of a first substrate holder takes place. The first substrate holder is preferably a substrate holder according to the invention.

In a second process step according to the invention, loading and fixing of a second substrate of a first substrate holder takes place. The first substrate holder is preferably a substrate holder according to the invention.

In a third process step according to the invention, an alignment of the two substrates with respect to one another takes place.

### The Alignment

preferably takes place with the aid of alignment marks, which are located on the substrate surfaces of the substrates. Suitable alignment systems, which can at the same time also be part of a device according to the invention, in particular a bonding chamber, are disclosed in publications U.S. Pat. No. 6,214,692E31, WO2015082020A1, WO2014202106A1, WO2018041326A1.

In a fourth process step according to the invention, a rough approach of the substrates towards one another takes place.

In a fifth process step according to the invention, the adjustment of a targeted, in particular homogeneous, curvature according to the invention of at least one of the substrates takes place with the aid of a substrate holder according to the invention. It is also conceivable for both substrates to be curved, in particular both with the aid of a substrate holder according to the invention. The, in particular homogeneous, curvature is enabled by the specially formed rear side of the fixing plate. In the case of the curvature which is adjustable in a targeted manner, the contact of the two substrates and therefore the initiation of a bonding wave eventually occurs.

For the sake of completeness, the following comment is made. If one of the substrate holders is not a substrate holder according to the invention, the latter can comprise a standard deformation element known in the prior art for a deformation of the substrate. This substrate holder not according to the invention then of course has all the negative consequences which are eliminated by the inventive idea of this document. It would however be conceivable for only a single substrate holder according to the invention to already suffice to produce a good bond, so that a standard substrate holder from the prior art can thus be used on the other side. The deformation element is then preferably a simple curving pin. This curving pin must not be confused with the much smaller pins of a pin substrate holder (pins chuck).

In a sixth process step according to the invention, the continuous, targeted and above all controlled release of the substrates from the substrate holders takes place. In particular, it is advantageous if at least the upper substrate holder is not only a substrate holder according to the invention, but also the fixings on its fixing surface can also be locally controlled in a targeted manner. This is primarily possible when the fixings have been grouped into zones, in particular vacuum zones, as has been disclosed in detail in publication WO2017162272A1.

An essential aspect according to the invention of the method according to the invention is therefore the curving of the substrate, which can be adjusted in a targeted manner, with the aid of a substrate holder according to the invention, which is possible only because no mechanical retrocoupling onto the substrate takes place in combination with a release of a substrate, which can be controlled in a targeted manner, from its fixing surface during the advance of the bonding wave.

Further advantages, features and details of the invention emerge from the following description of preferred examples of embodiment and with the aid of the drawings.

### BRIEF DESCRIPTION OF DRAWINGS

FIG. 1a shows an initial state of a substrate holder in the prior art,

FIG. 1b shows a final state of a substrate holder in the prior art,

FIG. 2a shows an initial state of a substrate holder according to the invention without a compensation plate,

FIG. 2b shows a final state of a substrate holder according to the invention without a compensation plate,

FIG. 3a shows an initial state of an extended substrate holder according to the invention with a compensation plate,

FIG. 3b shows a final state of an extended substrate holder according to the invention with a compensation plate,

FIG. 4 shows a first embodiment according to the invention of a substrate holder according to the invention with a compensation plate,

FIG. 5 shows a second embodiment according to the invention of a substrate holder according to the invention with a compensation plate,

FIG. 6a shows a third, preferred embodiment according to the invention of a substrate holder with a compensation plate in a side and plan view in an initial state,

FIG. 6b shows a third, preferred embodiment according to the invention of a substrate holder with a compensation plate in a side view in a final state.

Identical components and components with the same function are denoted with the same reference numbers in the figures.

### DETAILED DESCRIPTION OF INVENTION

The following two descriptions of the figures and their respective figures, which show two states of a substrate holder in the prior art, are kept as general as possible in order to illustrate the basic concept. It concerns a description that is as simple as possible and schematic diagrams, with no claim to completeness.

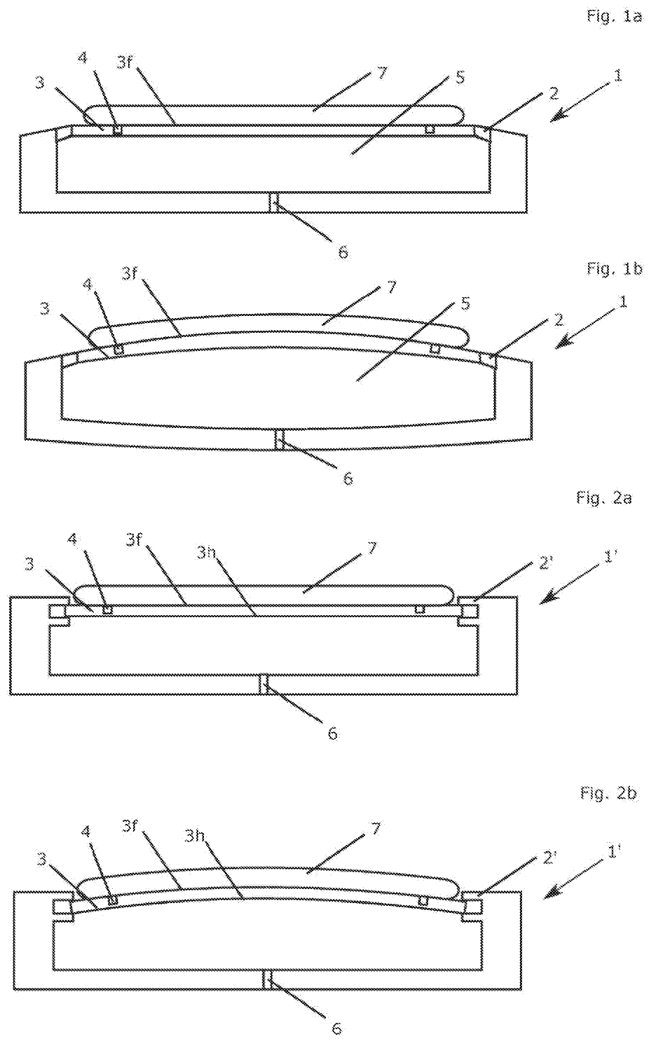

FIG. 1a shows a diagrammatic representation of an initial state of a substrate holder 1 in the prior art, the fixing plate surface 3f whereof can be curved. Substrate holder 1 comprises a fixing plate 3, which can be mounted in particular by means of a plate bearing 2, in particular at the periphery. In the present case, plate bearing 2 is in particular a fixed bearing, which in particular is also not designed hinged. It would of course also be conceivable for fixing plate 3 to be connected mechanically directly to the remainder of substrate holder 1. It is important that there is a surface described as fixing plate surface 3f, which can be curved. Fixing plate 3 is therefore designed and/or mounted such that it can be curved.

In particular, substrate fixings 4 are present on plate 3, with the aid of which a substrate 7 can be fixed on plate 3. As to how substrate fixings 4 are controlled, this is not relevant for an understanding of the device from the prior art and will not be explained in greater detail here.

FIG. 1b shows a diagrammatic representation of a final state of a substrate 1 in the prior art. In this special case, substrate holder 1, when viewed from outside, is curved in a convex manner, because an overpressure is built up in hollow 5. The overpressure arises due to the fact that, via an adjustment means 6, in the special case an opening, a valve or a nozzle, a gas or gas mixture with an overpressure relative to the surrounding atmosphere flows into hollow 5. Adjustment means 6 can alternatively be a mechanical adjustment means. The use of an overpressure is thus described here merely by way of example.

In this state, a number of fundamental problems arise. The first problem is that the curvature of fixing plate surface 3f, and therefore also of substrate 7, is generally inhomogeneous, i.e. the curvature changes, generally with the location. This is a generally undesired state. The inhomogeneity of the curvature can only be detected with difficulty in the figure. This problem is thus primarily connected with the fact that bearings 2 are designed as fixed bearings, i.e. the number of degrees of freedom is too small or even zero.

Bearings 2, which are usually designed such that they can transfer reaction forces and/or moments to fixing plate 3, are therefore a further problem in the prior art. In particular, bearings 2 in the prior art are not designed hinged. Bearings 2 in the prior art are therefore usually capable of transferring a moment.

A further problem is that an arbitrary adjustment element 6, which is responsible for the deformation of fixing plate 3, always produces a counterforce. Generally speaking, and expressed in physical terms, according to Newton's third law a counterforce arises, standardised to the area a corresponding counter-pressure, which bends substrate holder 1 in the other direction. This undesired curving of substrate holder 1 retroacts in particular on plate bearing 2 and thus also influences the curving behaviour of fixing plate 3, as well as the curving of substrate 7 fixed on fixing plate 3.

This is connected with the aforementioned problem that plate bearing 2 in the prior art is designed such that reaction forces and/or moments can be transferred. Even if a final state is adjusted in control-related terms, a retroaction via substrate holder 1 can be found, which is absolutely undesired, since measurements have shown that a bonding result to be implemented is thus made worse. It is explicitly mentioned and emphasised that the aforementioned mechanical retrocoupling effects obviously do not depend on the type of adjustment means 6, in the present illustrative case an opening through which a gas or a gas mixture flows, just as little as on the presence of a hollow 5.

Adjustment means 6 can just as well be a mechanical adjustment means, a pin, piezo pile, a bellows or any other adjustment means which can curve fixing plate 3. In these cases, there would probably also be no corresponding hollow 5. The fundamental physical law always demands that a mechanical retrocoupling takes place on the substrate holder.

The following descriptions of the figures and/or the figures, which each show two states of two substrate holder's 1′, 1″ according to the invention, are kept as general as possible, in order to illustrate the basic concept. It concerns a description that is as simple as possible and schematic diagrams, without any claim to completeness. The embodiments according to the invention are then described in greater detail in further figures.

The inventive idea is again illustrated with the aid of a device, in which a fluid is used in order to create an overpressure in hollow 5, which curves fixing plate 3 on which substrate 7 is fixed. It is again emphasised that the inventive idea is not bound to the use of a fluid and/or a hollow 5. The inventive aspect could be implemented just as well with the aid of mechanical, pneumatic, electrical, piezoelectrical adjustment means 6, as will subsequently be shown and demonstrated in special embodiments.

FIG. 2a shows a diagrammatic representation of an initial state of a substrate holder 1′ according to the invention with which at least one homogeneous curvature can be adjusted. It is assumed that substrate 1′ has such a great bending resistance that the problem of the mechanical retrocoupling, the elimination or reduction of which is described in greater detail in subsequent figures, does not yet occur here. An increase in the bending resistance can for example be achieved very easily, in that several components of substrate holder 1′, in particular substrate holder 1′ as a whole, are designed thicker. Bearing 2′ is important, which is produced such that no or only very small reaction forces and/or moments are transferred to fixing plate 3. In particular, the shape of hollow plate surface 3h is selected such that subsequent curving of fixing plate 3 produces a well-defined, in particular homogeneous, curvature.

FIG. 2b shows a diagrammatic representation of a final state of a substrate holder 1′ according to the invention, with which at least one homogeneous curvature can be adjusted. Even if substrate holder 1′ according to the invention has a higher bending resistance, it must nonetheless, even though only to a small extent, also be slightly curved when an adjustment means 6 is used. This curvature is however relatively small on account of the relatively high bending resistance. Nonetheless, forces and/or moments arise, which would be transferred to fixing plate 3 without bearing 2′.

By means of special bearing 2′, a still well-defined, in particular homogeneous, curvature on fixing surface 3f and therefore substrate 7 can be adjusted, since possible reaction forces and/or moments are not transferred, or are so only to a small extent, to fixing plate 7. Bearing 2′ assists the formation of a homogeneous curvature in addition to the components already produced in a solid construction. In the special case, an adjustment means 6 is used to adjust the curvature, wherein it is an opening, a nozzle or a valve, to which a fluid, in particular a gas mixture, preferably air, is pressed.

Through the use of a fluid, the embodiment according to the invention with the specially shaped hollow plate surface 3h acquires particular significance. Through the use of a fluid, which exerts a homogeneous and isotropic pressure on hollow plate surface 3h, a force distribution assumed along hollow plate surface 3h in which the forces are always normal to hollow plate surface 3h can be assumed.

On this assumption, it is particularly easy with the aid of numerical simulations, in particular finite elements methods, to calculate a suitable shape of hollow plate surface 3f, in order to obtain the desired, in particular homogeneous, curvature on fixing surface 3f, and therefore on fixed substrate 7. Such a special shape of hollow plate surface 3f improves still further the formation of a homogeneous curvature of fixing plate surface 3f and therefore of substrate 7.

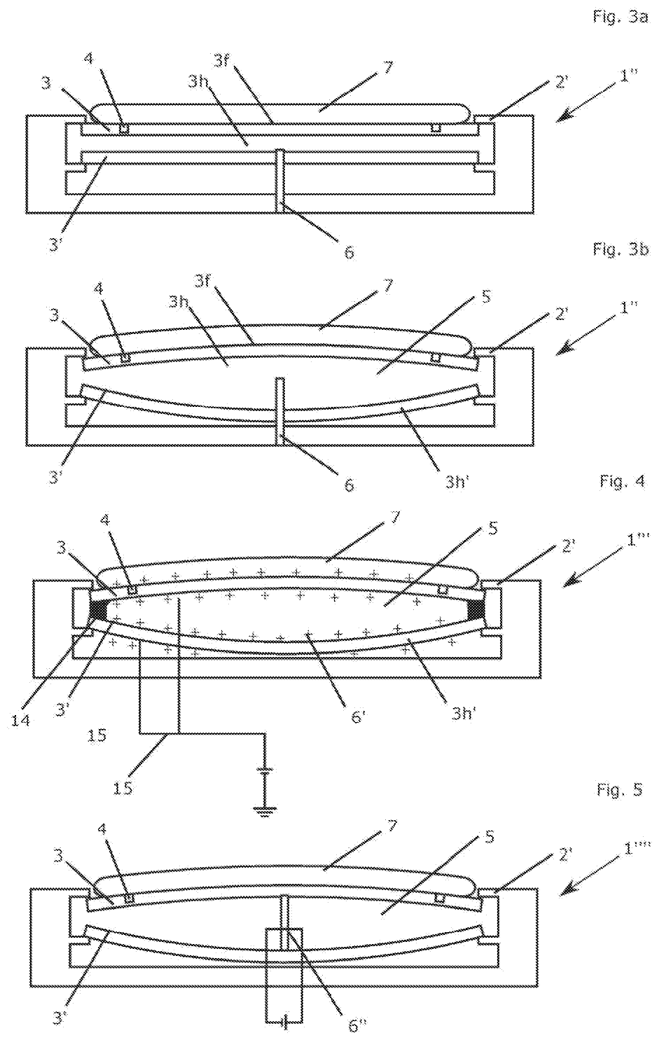

FIG. 3a shows a diagrammatic representation of an initial state of a further improved substrate holder 1″ according to the invention, with which at least one homogeneous curvature can be adjusted and with which harmful influences of mechanical retrocoupling on plate holder 2′ can be further minimised. Such an improvement according to the invention is especially advantageous when substrate holder 1″ has been designed relatively thin and has a very small bending resistance.

The mechanical retroaction can then no longer be ignored and should at least be reduced, preferably completely eliminated, by the improved embodiment according to the invention. The advantages of the specially shaped hollow plate surface 3h will not be dealt with further here. Substrate holder 1″ comprises a fixing plate 3 and a compensation plate 3′, which are mounted by means of a plate bearing 2′. Plates 3, 3′ are designed and/or mounted such that they can be curved.

For the sake of completeness, it is mentioned that plate 3, from the theoretical viewpoint, must not be an independent component, but could rather be part of substrate holder 1′. Only the presence of a fixing plate surface 3f is important.

However, boundary conditions would thus arise, which make the production of a constant curvature of fixing plate surface 3f almost impossible. The most preferred embodiment according to the invention thus makes provision such that fixing plate 3 represents an independent component. The inventive effect is thus primarily in the use of a compensation plate 3′.

In the subsequent description of the figures, therefore, each embodiment according to the invention is represented with the preferred design-related solution of two plates. In particular, substrate fixings 4 are located on fixing plate 3, with the aid of which a substrate 7 can be fixed on fixing plate 3. As to how substrate fixings 4 are controlled, this is not relevant for an understanding of the device and will not be explained further here. It is shown in the following figures how substrate fixings 4, which are constituted as vacuum fixings, are controlled.

FIG. 3b shows a diagrammatic representation of a final state of further improved substrate holder 1″ according to the invention. By means of an adjustment means 6, in the present special case an opening, a valve or a nozzle, a fluid is pressed into a hollow 5, which leads to curving of the two plates 3, 3′. In contrast with the prior art according to figure la, no curving of fixing 2 or other parts of substrate holder 1′ takes place and therefore no additional moment, acting by fixing 2, arises on fixing plate 3 and substrate 7 fixed thereon. The curving of fixing plate 3 thus takes place only through the effect of adjustment means 6.

Compensation plate 3′ can thus be regarded as a kind of “sacrificial plate”, the sole purpose of which is preventing or at least minimising the force effect on the remaining components of substrate holder 1′. In the special case, plates 3, 3′, in particular at their periphery, must be sealed. The representation of the details, in particular of the seal, is dispensed with for the sake of clarity in this schematic diagram. The seal will however be dealt with in greater detail and a subsequently represented figure of the most preferred embodiment.

In the further figures, the different embodiments according to the invention are dealt with and represented individually and in detail.

FIG. 4 shows a first, preferred embodiment according to the invention, wherein the two plates 3, 3′ are set as an electrical potential with the same sign, in particular the same value. In order to prevent the two plates 3, 3′ forming an electrically conductive self-contained body, plate 3, 3′ must be electrically insulated from one another at their contact points by means of electrical insulation 14. Otherwise, according to the laws of physics, all the charges at hollow plate surfaces 3h, 3h′, which form hollow 5, would migrate outwards.

The self-contained body would form a Faraday cage and would enable the storage of charge only at the outer side. Electrical insulation 14 ensures that the two plates 3, 3′, from the electrostatic viewpoint, do not form a self-contained conductive body, but each form a conductive body. The generation of charges at the substrate surfaces, which form hollow 5, is thus possible. The charges present on hollow plate surfaces 3h, 3h′ or the two plates 3, 3′ themselves accordingly represent, together with required electric circuit 15, adjustment means 6′.

FIG. 5 shows a second, preferred embodiment according to the invention, wherein an adjustment means 6″ is present between the two plates 3, 3′. Adjustment means 6″ can for example be an electrically and/or pneumatically and/or hydraulically controllable mechanical adjustment means. The use of an electrically controllable piezo pile would also be conceivable. Adjustment means 6″ could also be two very strong electric magnets, which create two magnetic fields in an electrically controlled manner and thus repel one another, so that the two plates 3, 3′ are driven apart. An embodiment would also be conceivable in which two plates are set at the same electrical potential and repel one another due to their electrostatic charge.

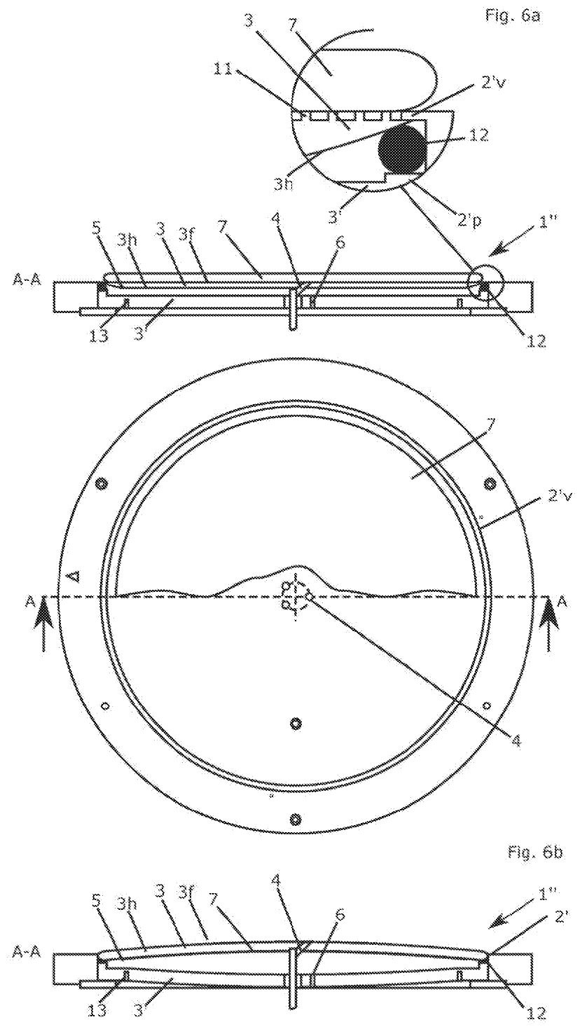

FIG. 6a shows the third preferred embodiment according to the invention in a side view, a detailed view and a plan view in an initial state. This embodiment according to the invention is an embodiment from FIGS. 3a and 3b described in very much more detail. The representation comprises (i) the specially produced bearing 2′, via which almost no or only very small reaction forces and/or moments can be transferred, as well as (ii) compensation plate 3′.

The importance of this embodiment is based primarily on the fact that a fluid is used for curving the two plates 3, 3′, which on account of a static pressure has an isotropic, i.e. uniform force effect on the two plates 3, 3′, but in particular fixing plate 3. All the aforementioned features in FIG. 6a can in particular also be used in the previously mentioned and dealt-with substrate holders of FIGS. 3 and 4. On account of the importance of this embodiment, they are however described in detail in this figure.

Fixing plate surface 3f of fixing plate 3 is preferably mounted or contacted at its periphery via a plate bearing projection 2′v and plate surface 3h of fixing plate 3 via a seal 12. Seal 12 again preferably lies on lower compensation plate 3′, and in particular on a plate bearing platform 2′p. Seal 12 seals the peripheries of plates 3, 3′ against one another and nonetheless permits the curving of the two plates 3, 3′.

At this point, it is mentioned once again that the curvatures are extremely small, i.e. the radii of curvature are very large. A point on an arbitrary surface of one of the two plates 3, 3′ is displaced in the z-direction by only some few nanometres, micrometres, but in the rarest cases by millimetres. Such small curvatures also make it possible to keep such a delicate structure mechanically stable. In particular, plate bearing projection 2′v can be constituted very fine.

Substrate 7 is fixed by substrate fixing 4. In the special case, the drawing shows that the parts of substrate fixing 4 extend through hollow 5. These parts are in particular constituted expandable. It can for example be a hose, a fed-in tube or any other line which is capable of evacuating the region between substrate 7 and fixing plate 3. In particular, there are a plurality of outlet openings of substrate fixing 3, which are arranged in particular symmetrically about the centre. It is thus made possible for a pin 11 to be located in the centre of fixing plate 3, which has a favourable effect on the bonding behaviour.

FIG. 6b shows the third, preferred embodiment according to the invention in a side view in a final state. Adjustment means 6, in this special case a non-concentric opening, a valve or a nozzle, pumps a fluid into hollow 5. Fixing substrate 3 is curved according to the invention. The curving of compensation plate 3′ preferably takes place up to a groove 13, which is introduced into compensation plate 3′ around the entire circumference.

The curving is thus concentrated on the central part of compensation plate 3′ and it is ensured that a still smaller moment and/or a still smaller force acts mechanically on plate bearing 2′, which in this case is comprised especially of a plate bearing projection 2′v, a seal 12 and a plate bearing platform 2′p (see enlarged view in FIG. 6a). As a result of this further design-related improvement according to the invention, a mechanical retrocoupling on fixing plate 3 is completely prevented or at least minimised to an extent such that it is negligible.

### LIST OF REFERENCE NUMBERS

1,1′,1″,1′″ Substrate holder
2, 2′ Plate bearing
2′v Plate bearing projection
2′p Plate bearing platform
3 Fixing plate
3′ Compensation plate
3f Fixing plate surface
3h, 3h′ Hollow plate surface
4 Substrate fixing
5 Hollow/intermediate space
6, 6′, 6″ Adjustment means/curving means
7 Substrate
11 Pins
12 Seal, in particular sealing ring
13 Groove
14 Electrical insulation
15 Electric circuit

1-12. (canceled)

13. A substrate holder for curving a substrate, said substrate holder comprising:
a fixing plate for fixing the substrate; and
curving means for curving the fixing plate,
wherein the fixing plate is comprised such that curvature of the substrate is adjustable in a targeted manner, and
wherein the fixing plate is mounted in a hinged manner.

14. The substrate holder according to claim 13, wherein thickness of the fixing plate varies.

15. The substrate holder according to claim 13, wherein a homogeneous curvature of the substrate is adjustable.

16. The substrate holder according to claim 13, wherein a rear side of the fixing plate is formed such that a homogeneous curvature of the fixing plate results.

17. The substrate holder according to claim 13, wherein reaction forces produced during the curving of the fixing plate can be compensated by at least one compensation means.

18. The substrate holder according to claim 17, wherein the at least one compensation means is a curvable compensation plate.

19. The substrate holder according to claim 13, wherein the fixing plate is thicker in the centre of the fixing plate than at the edge of the fixing plate.

20. The substrate holder according to claim 13, wherein the fixing plate is formed tapered towards the edge of the fixing plate.

21. The substrate holder according to claim 13, wherein the fixing plate is formed symmetrically with respect to the centre of the fixing plate.

22. A bonding device comprising at least one substrate holder according to claim 13.

23. A method for bonding first and second substrates, comprising the following steps,
fixing the first substrate on a first substrate holder according to claim 13;
fixing the second substrate on a second substrate holder according to claim 13;
aligning the first and second substrates with respect to one another, wherein at least one of the first and second substrates is curved;
bringing the first and second substrates into contact with each other;
adjusting curvature of at least one of the first and second substrates in a targeted manner.

24. The method according to claim 23, wherein the curvature of at least one of the first and second substrates is adjusted homogeneously.
